(19) United States
(12) Patent Application Publication
(10) Pub. No.: US 2003/0095673 A1
(43) Pub. Date: May 22, 2003

(54) Audio-based method and apparatus for controlling operation of an appliance

(75) Inventors: Antonio J. Colmenarez, Maracaibo (VE); Srinivas Gutta, Yorktown Heights, NY (US); Miroslav Trajkovic, Ossining, NY (US)

Correspondence Address: Corporate Patent Counsel, U.S. Philips Corporation, 580 White Plains Road, Tarrytown, NY, 10591, US

(73) Assignee: Koninklijke Philips Electronics N.V.

(21) Appl. No.: 09/988,942

(22) Filed: Nov. 19, 2001

(51) Int. Cl. H04R 3/00; H03G 3/20; G10L 11/00

(52) U.S. Cl. 381/110; 704/275

(57) ABSTRACT

An appliance controller is disclosed that monitors the operation of an appliance and automatically adjusts the appliance in response to predefined audio activity. The disclosed appliance controller includes one or more microphones to capture audio information associated with an appliance. A number of exemplary appliance adjustment rules define various audio features that suggest when an appliance setting should be adjusted. Each rule contains one or more audio features and a corresponding appliance adjustment that should be performed when the rule is satisfied. The appliance adjustment rules can be predefined or dynamically determined from observed user behavior.

### FIELD OF THE INVENTION

The present invention relates to methods and apparatus for controlling appliances and other devices, such as food processors, mixers and microwave ovens, and more particularly, to an audio-based method and apparatus for automatically detecting when a task performed by an appliance has been completed based on specified sound patterns and to automatically trigger a subsequent step (if any) or terminate the operation of an appliance.

### BACKGROUND OF THE INVENTION

The marketplace offers a number of consumer appliances, such as microwave ovens, food processors, mixers and blenders, that provide an ever-growing number of features intended to increase the convenience and capabilities of these appliances. Most appliances, for example, have a one-touch feature that allows the appliance to be activated in a desired mode with the press of only a single button. Thereafter, the appliance can typically operate in the desired mode in an unattended manner until the human operator deactivates the appliance, allowing the human operator to perform other tasks while the appliance performs the desired primary task.

While such features have greatly improved the convenience of many appliances, they still require the affirmative action of the user to terminate or deactivate the appliance or to adjust the configuration of the appliance for a subsequent task. Thus, even though the appliance may not require any direct human intervention during the performance of the primary task, the user must nonetheless pay attention to the operation of the appliance to determine when the appliance should be manually terminated or adjusted for a subsequent step. For many tasks, such as the mixing of certain types of bread dough, the precise time at which the appliance is stopped or adjusted may be critical. Thus, if the user becomes distracted while performing another task, the intended result of the primary task may not be achieved.

It has been observed that there is often a predictable relationship between certain sound activity of an appliance and a corresponding manner in which the settings of an appliance should be adjusted. For example, when certain ingredients are combined in a mixer, the mixing task is complete when the sound emanating from the mixer demonstrates a certain pitch or another predictable audio feature. Similarly, it is well known that microwave popcorn is finished popping when there is an absence of a popping sound for a specified interval and that water in kettle has boiled when the kettle begins to whistle.

There is currently no mechanism, however, that can correlate the audio activity of an appliance to a corresponding adjustment to the appliance. A need therefore exists for an appliance controller that monitors audio activity from an appliance and automatically adjusts the appliance in response to predefined audio activity. A further need exists for an appliance controller that can learn the correlation between the audio activity of an appliance and a corresponding adjustment to the appliance.

### SUMMARY OF THE INVENTION

Generally, a method and apparatus are disclosed for monitoring audio activity associated with an appliance and automatically adjusting the appliance in response to predefined audio features. The disclosed appliance controller includes one or more microphones focused on one or more appliances.

According to one aspect of the invention, a number of appliance adjustment rules define various audio features that suggest when an appliance setting should be adjusted. Each rule contains one or more specified audio features and a corresponding appliance adjustment that should be performed when the rule is satisfied. The detected audio feature may be a static audio characteristic, such as a specified pitch or volume, or a time varying audio characteristic, such as a specified pitch or volume over an interval of time.

The appliance adjustment rules may be predefined or dynamically determined by observing user behavior during a learning phase. In a learning phase, a classifier learns distinguishing audio features when a user makes a manual adjustment. During operation of the appliance, the appliance is automatically adjusted when the observed audio features are again detected.

A more complete understanding of the present invention, as well as further features and advantages of the present invention, will be obtained by reference to the following detailed description and drawings.

### BRIEF DESCRIPTION OF THE DRAWINGS

FIG. 1 illustrates an appliance controller in accordance with the present invention;

FIG. 2 illustrates a sample table from the appliance adjustment rules database of FIG. 1 in accordance with the present invention;

FIG. 3 illustrates an exemplary appliance learning process embodying principles of the present invention; and

FIG. 4 is a flow chart describing an exemplary appliance monitoring process embodying principles of the present invention.

### DETAILED DESCRIPTION

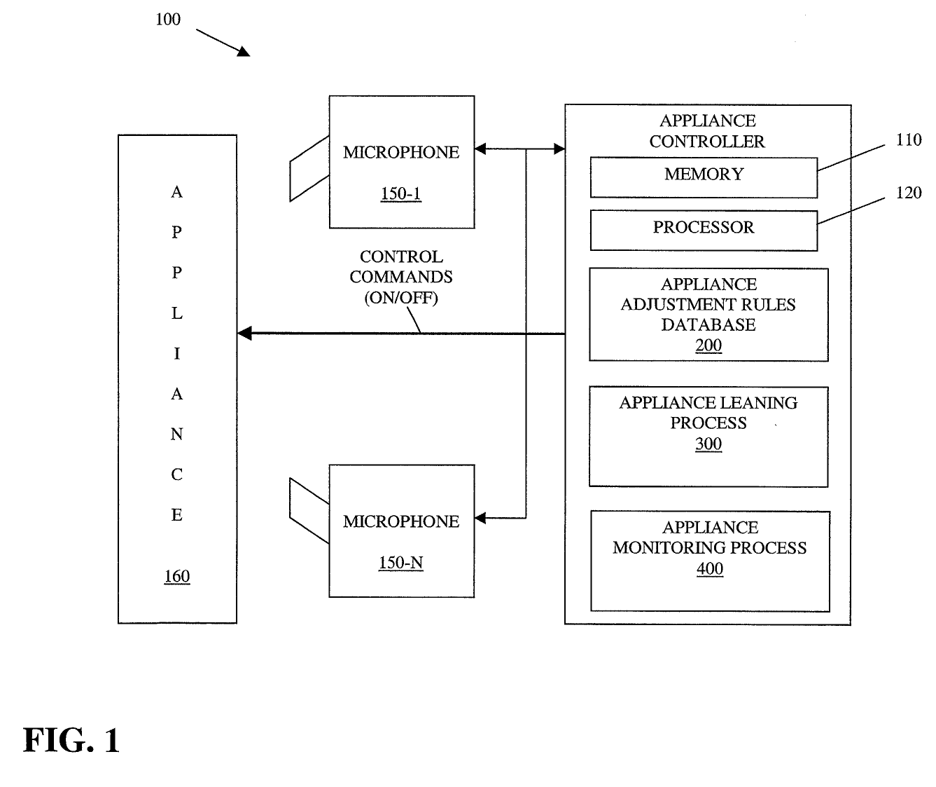

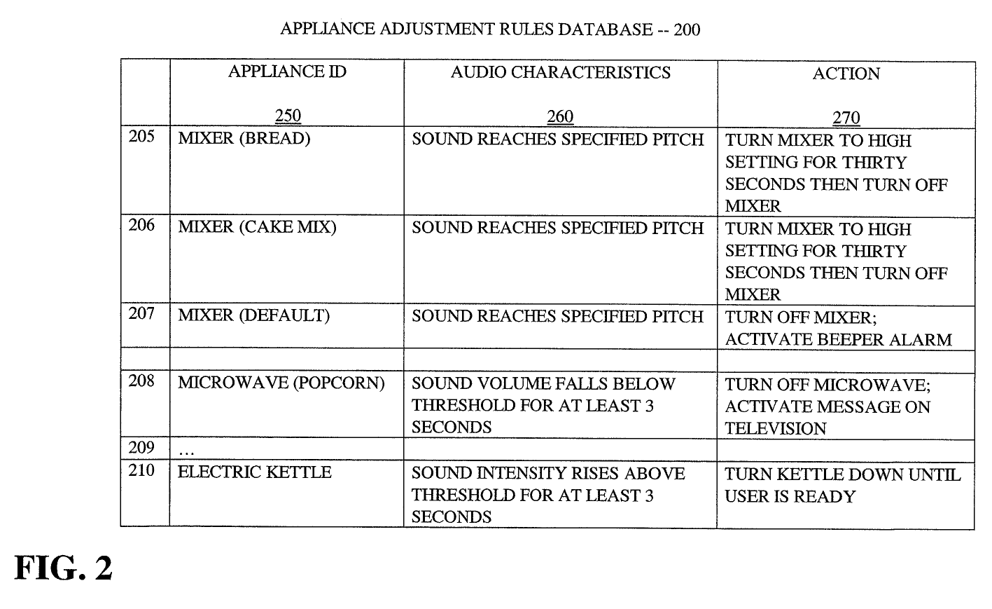

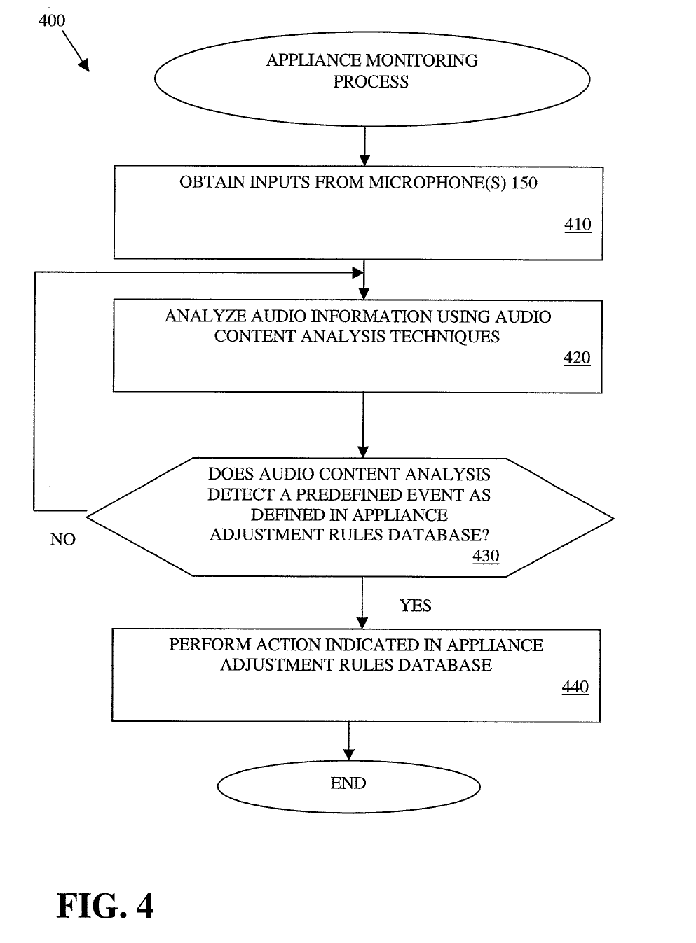

FIG. 1 illustrates an appliance controller 100 in accordance with the present invention. As shown in FIG. 1, the appliance controller 100 includes one or more microphones 150-1 through 150-N (hereinafter, collectively referred to as microphones 150) that are focused on one or more appliances 160, such as a microwave oven, food processor, mixer or blender. The audio information generated by the microphones 150 is processed by the appliance controller 100, in a manner discussed below in conjunction with FIG. 4, to identify one or more predefined audio events suggesting that the appliance(s) should be adjusted. In one implementation, the present invention employs an appliance adjustment rules database 200, discussed further below in conjunction with FIG. 2, that identifies a number of audio characteristics that should initiate the adjustment of the appliance 160 in a specified manner.

As discussed further below, each appliance adjustment rule contains one or more audio features that must be observed in order for the rule to be triggered, and a corresponding appliance adjustment that should be performed by the appliance controller 100 when the predefined criteria for initiating the appliance adjustment rule is satisfied. At least one of the criteria for each rule is an audio feature detected in the audio information generated by the microphones 150. The detected audio feature may be a static audio characteristic, such as a specified pitch or volume, or a time varying audio characteristic, such as a specified pitch or volume over an interval of time. Upon detection of a predefined audio feature, the appliance controller 100 automatically adjusts the appliance in a specified manner.

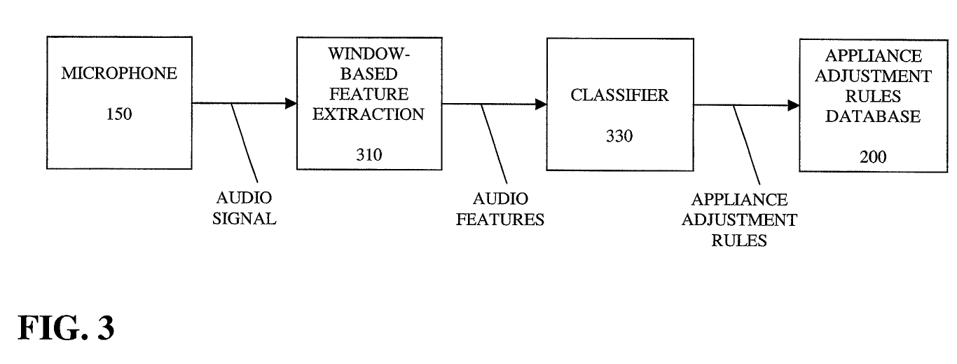

As discussed below in conjunction with FIGS. 2 and 3, the exemplary appliance adjustment rules recorded in the audio adjustment rules database 200 may include a number of default rules that have been installed, for example, during a manufacturing or upgrade process, and optionally, additional rules that are dynamically learned by the appliance controller 100 based on user activity.

As shown in FIG. 1, and discussed further below in conjunction with FIGS. 3 and 4, the appliance controller 100 includes an appliance learning process 300 and an appliance monitoring process 400. Generally, the appliance learning process 300 observes the operation of one or more appliances 160 to learn a set of appliance adjustment rules that define when a given appliance 160 should be adjusted based on observed audio characteristics. The appliance monitoring process 400 processes the audio information obtained by the microphones 150 and detects one or more predefined actions that should trigger the adjustment of an appliance 160.

The appliance controller 100 may be embodied as any computing device, such as a personal computer or workstation, that contains a processor 120, such as a central processing unit (CPU), and memory 110, such as RAM and/or ROM. Alternatively, the appliance controller 100 may be embodied as an application specific integrated circuit (ASIC) (not shown) that is included, for example, in an appliance.

FIG. 2 illustrates an exemplary table of the audio adjustment rules database 200 that records various rules for one or more appliances. Each rule in the audio adjustment rules database 200 identifies the corresponding appliance and includes predefined criteria specifying the conditions under which the rule should be initiated, as well as a corresponding action item that should be triggered when the criteria associated with the rule is satisfied. Typically, the action item identifies the manner in which the appliance(s) 160 should be adjusted when the rule is triggered.

As shown in FIG. 2, the audio adjustment rules database 200 is comprised of a plurality of records, such as records 205-210, each associated with a different appliance adjustment rule. For each rule, the audio adjustment rules database 200 identifies the corresponding appliance in field 250 (and possibly a particular task performed by the appliance, such as mixing bread dough), the corresponding rule criteria in field 260 and the corresponding action in field 270.

For example, the exemplary appliance adjustment rule set forth in record 206 defines an audio characteristic (a specified sound pitch) that should trigger turning a mixer to a high speed for a specified interval. Similarly, the exemplary appliance adjustment rule set forth in record 208 defines an audio characteristic (an absence of sound for a specified time interval when popcorn is popping) that should trigger turning off the microwave oven.

As previously indicated, the appliance adjustment rules recorded in the audio adjustment rules database 200 may include a number of default rules that have been pre-installed, for example, during the manufacturing process, and optionally, additional rules that are dynamically learned by the appliance controller 100 based on user activity.

FIG. 3 illustrates an exemplary appliance learning process 300 that may be employed in an exemplary embodiment to generate appliance adjustment rules. As previously indicated, the appliance learning process 300 observes the operation of one or more appliances 160 to learn a set of appliance adjustment rules that define when a given appliance 160 should be adjusted based on observed audio characteristics.

As shown in FIG. 3, the microphones 150 capture an audio signal that includes audio activity associated with the operation of an appliance 160. Thereafter, a window-based feature extraction is performed at stage 310 to generate audio feature intervals, such as 10 millisecond intervals. A classifier 330 processes the audio features to correlate audio activity with manual adjustments by a user during a learning phase. In this manner, the classifier 330 generates appliance adjustment rules that are recorded in the audio adjustment rules database 200. Generally, the classifier 330 learns distinguishing audio features when a user makes a manual adjustment that can later be applied to automatically make the same adjustment to an appliance 160 when the observed audio features are again detected during operation of the appliance 160.

The classifier 330 may be embodied, for example, as a Bayesian classifier or a decision tree (DT) classifier, such as those described in U.S. patent application Ser. No. ______, filed ______, entitled “CLASSIFIERS USING EIGEN NETWORKS FOR RECOGNITION AND CLASSIFICATION OF OBJECTS,” (Attorney Docket No. US010566), assigned to the assignee of the present invention and incorporated by reference herein.

FIG. 4 is a flow chart describing an exemplary appliance monitoring process 400. The appliance monitoring process 400 processes the audio information obtained by the microphones 150 and detects one or more predefined actions that should trigger the adjustment of an appliance 160. The exemplary appliance monitoring process 400 is a general process illustrating the broad concepts of the present invention.

As shown in FIG. 4, the appliance monitoring process 400 initially obtains one or more inputs from the microphones 150 during step 410. Thereafter, the appliance monitoring process 400 analyzes the audio information during step 420 using audio content analysis techniques. For a detailed discussion of suitable audio content analysis techniques, see, for example, Silvia Pfeiffer et al., “Automatic Audio Content Analysis,” Proc. ACM Multimedia 96, 21-40, Boston, Mass. (November 1996), or Dongge Li et al., “Classification of General Audio Data for Content-Based Retrieval,” Pattern Recognition Letters 22, 533-44 (2001), each incorporated by reference herein. Generally, the audio content analysis is employed to recognize various features in the audio signals obtained by the microphones 150.

A test is performed during step 430 to determine if the audio content analysis detects a predefined event, as defined in the audio adjustment rules database 200. If it is determined during step 430 that the audio content analysis does not detect a predefined event, then program control returns to step 420 to continue monitoring the audio information in the manner discussed above.

If, however, it is determined during step 430 that the audio content analysis does detect a predefined audio event, then the audio event is processed during step 440 as indicated in field 270 of the audio adjustment rules database 200 for the identified appliance. Program control then terminates (or returns to step 410 and continues monitoring user activities in the manner discussed above).

It is to be understood that the embodiments and variations shown and described herein are merely illustrative of the principles of this invention and that various modifications may be implemented by those skilled in the art without departing from the scope and spirit of the invention.

What is claimed is:

1. A method for controlling an appliance, comprising:
analyzing audio information associated with said appliance to identify at least one predefined audio characteristic; and
automatically adjusting said appliance when said predefined audio characteristic is identified.

2. The method of claim 1, wherein said predefined audio characteristic indicates that said appliance should be turned off.

3. The method of claim 1, wherein said predefined audio characteristic indicates that a configuration of said appliance should be adjusted.

4. The method of claim 1, wherein said predefined audio characteristic is a static audio characteristic.

5. The method of claim 1, wherein said predefined audio characteristic is a time varying audio characteristic.

6. The method of claim 1, wherein said predefined audio characteristic and said corresponding adjustment are obtained during a learning phase.

7. The method of claim 1, wherein said predefined audio characteristic and said corresponding adjustment are a default setting.

8. A method for controlling an appliance, comprising:
establishing at least one appliance adjustment rule, said appliance adjustment rule including at least one predefined audio characteristic associated with said appliance and an action item to be performed to automatically adjust said appliance when said rule is satisfied;
analyzing audio information associated with said appliance to identify said at least one predefined audio characteristic; and
performing said action item if said appliance adjustment rule is satisfied.

9. The method of claim 8, wherein said predefined audio characteristic indicates that said appliance should be turned off.

10. The method of claim 8, wherein said predefined audio characteristic indicates that a configuration of said appliance should be adjusted.

11. The method of claim 8, wherein said predefined audio characteristic is a static audio characteristic.

12. The method of claim 8, wherein said predefined audio characteristic is a time varying audio characteristic.

13. The method of claim 8, wherein said establishing step further comprises the step of learning a correlation between said predefined audio characteristic and said corresponding adjustment.

14. The method of claim 8, wherein said establishing step further comprises the step of installing one or more default settings indicating said predefined audio characteristic and said corresponding adjustment in said appliance.

15. The method of claim 8, wherein said appliance adjustment rule includes one or more settings for said appliance that should be established when said appliance adjustment rule is satisfied.

16. A system for controlling an appliance, comprising:
a memory for storing computer readable code; and
a processor operatively coupled to said memory, said processor configured to:
analyze audio information associated with said appliance to identify at least one predefined audio characteristic; and
automatically adjust said appliance when said predefined audio characteristic is identified.

17. A system for controlling an appliance, comprising:
a memory for storing computer readable code; and
a processor operatively coupled to said memory, said processor configured to:
establish at least one appliance adjustment rule, said appliance adjustment rule including at least one predefined audio characteristic associated with said appliance and an action item to be performed to automatically adjust said appliance when said rule is satisfied;
analyze audio information associated with said appliance to identify said at least one predefined audio characteristic; and
perform said action item if said appliance adjustment rule is satisfied.

18. An article of manufacture for controlling an appliance, comprising:
a computer readable medium having computer readable code means embodied thereon, said computer readable program code means comprising:
a step to analyze audio information associated with said appliance to identify at least one predefined audio characteristic; and
a step to automatically adjust said appliance when said predefined audio characteristic is identified.

19. An article of manufacture for controlling an appliance, comprising:
a computer readable medium having computer readable code means embodied thereon, said computer readable program code means comprising:
a step to establish at least one appliance adjustment rule, said appliance adjustment rule including at least one predefined audio characteristic associated with said appliance and an action item to be performed to automatically adjust said appliance when said rule is satisfied;
a step to analyze audio information associated with said appliance to identify said at least one predefined audio characteristic; and
a step to perform said action item if said appliance adjustment rule is satisfied.

20. A system for controlling an appliance, comprising:
means for analyzing audio information associated with said appliance to identify at least one predefined audio characteristic; and
means for automatically adjusting said appliance when said predefined audio characteristic is identified.
